(19) United States
(12) Patent Application Publication
(10) Pub. No.: US 2007/0262712 A1
(43) Pub. Date: Nov. 15, 2007

(54) Segmented Electroluminescent Panel

(76) Inventors: Robert Gustar, Camberly (GB); Mark Southgate Walter, Epsom (GB); Mike Bobeckyj, Sandhurst (GB)

Correspondence Address: BLAKELY SOKOLOFF TAYLOR & ZAFMAN, 1279 OAKMEAD PARKWAY, SUNNYVALE, CA, 94085-4040, US

(21) Appl. No.: 10/552,644

(22) PCT Filed: Apr. 7, 2004
(86) PCT No.: PCT/EP04/50475

§ 371 Date: Mar. 2, 2007

(30) Foreign Application Priority Data
Apr. 9, 2003 (GB) 0308161.9

(51) Int. Cl. H01J 1/62

(52) U.S. Cl. 313/509; 313/506

(57) ABSTRACT

A light-emitting panel comprises a transparent substrate having a plurality of electroluminescent elements on the surface thereof. Dielectric elements are located between the electroluminescent elements, each being in contact with a conductive element in contact with the dielectric elements. A voltage can be applied across each electroluminescent element without the need for an expensive transparent conductive layer.

The present invention relates to light-emitting panels, and in particular, although not exclusively, to segmented electroluminescent panels for use in illuminated road signs.

Road signs are used to inform drivers of road conditions and regulations as they relate to the area in which the sign is located. Many such signs are currently made using a “retro-reflective” material, that is, a material which reflects light directly back in the direction from which it came. This property greatly increases the visibility of such signs at night by allowing light from the headlights of passing vehicles to be reflected straight back towards the driver. However, such signs can only be seen at night when they fall within the beam of a vehicle's headlights.

Earlier awareness of the road conditions and regulations gives a driver additional time to respond to such information, reducing the likelihood of accidents. It is therefore sometimes desirable to provide illuminated signs which can be seen at night even when they are not illuminated by headlights. One such illuminated sign is disclosed in WO00/48166. A sign panel is illuminated from behind by a flat panel of electroluminescent material. The front of the sign comprises a retro-reflective lens. The sign also includes a photodetector for measuring ambient light, and the electroluminescent material is only activated so as to emit light when the ambient light falls below a predetermined level—i.e. during the night.

Electroluminescent materials have a finite lifetime. For example, a typical material may initially generate light at 34.6 cd m⁻² when supplied with alternating current at 100V and 400 Hz. After 3,500 hours of continuous use, the light emitted under these conditions will have fallen to 30% of its initial brightness. One way to increase the lifetime of an electroluminescent light source is to decrease the voltage and/or frequency of the electricity supplied: for example, the material just described, if supplied at 100V ac and 60 Hz, reduces to 30% brightness after 20,000 hours. However, the initial brightness is also reduced so the increased lifetime comes at a cost

In addition, most electroluminescent panels currently available are optimised to produce high brightness, with longevity a secondary consideration. If the power levels provided to a typical panel are reduced in an effort to prolong its life, the panel will no longer run at its optimum power requirement. The increase in the life of the panel will not be as pronounced as the decrease in brightness of the panel.

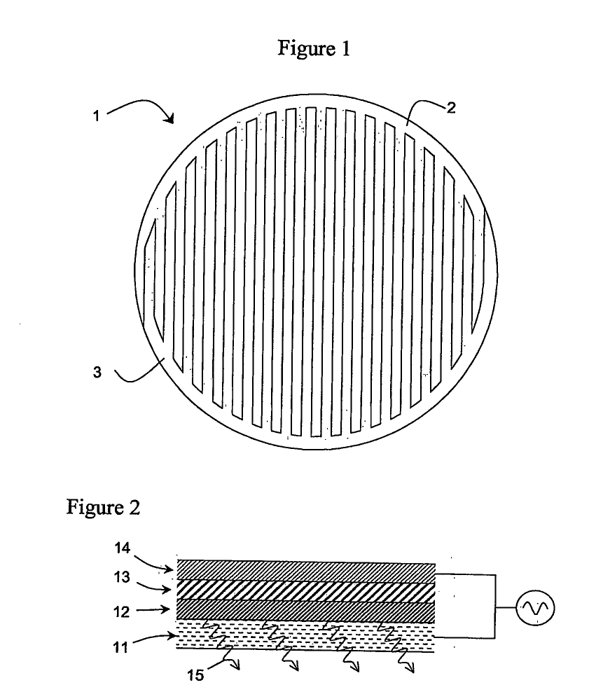

One solution to this problem is shown in FIG. 1, and involves the production of a panel 1 comprising arrays 2, 3 of alternating strips of electroluminescent material which can be activated independently of each other. The strips can be printed with dimensions such that, from a distance, it is not possible to tell that some of the strips are illuminated and some are not. The whole panel can therefore be illuminated by activating only one of the arrays 2, 3 of strips.

If such a panel is used to illuminate a road sign, this means that the sign can be illuminated at a lower level of brightness by activating one of the arrays 2 at its optimum power requirement. The other array 3 may then be activated on the following day, so that at any one time the sign is lit by only one array. The arrays 2, 3 would then continue to be activated on alternate days. This doubles the lifetime of each array of electroluminescent material, and allows each array to operate at its optimum power requirement. If higher brightness is required, both arrays could be activated simultaneously.

FIG. 2 shows a cross-section through a typical electroluminescent panel (non-segmented) which could be used to illuminate a road sign. The panel is intended to be placed behind a transparent retroreflective layer (not shown). The panel includes a conductive transparent layer 11, an electroluminescent layer 12, a dielectric layer 13 and a conductive layer 14.

In order to activate the electroluminescent layer 12, an alternating voltage is provided between the conductive transparent layer 11 and the conductive layer 14. This causes the electroluminescent layer 12 to emit light 15 which passes through the conductive transparent layer 11 and the transparent retroreflective layer (not shown). Such a panel is simple to manufacture, although conductive transparent material is expensive, and may need to be deposited in a vacuum onto a transparent substrate which forms the window of the panel. A typical conductive transparent material is Indium Tin Oxide (ITO).

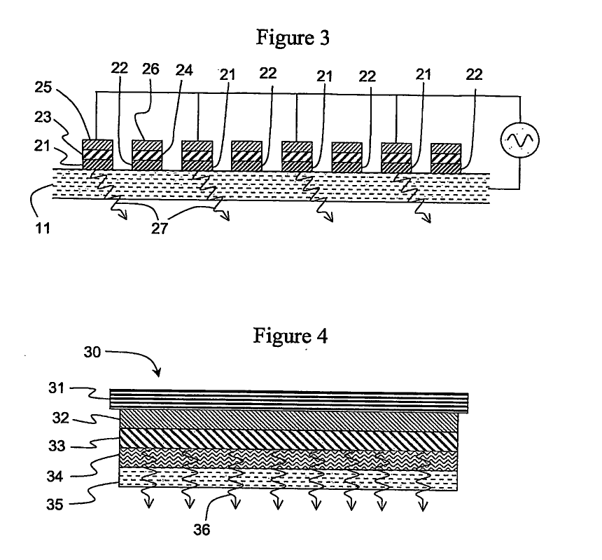

In order to produce a “segmented” electroluminescent panel (i.e. one having more than one array), each electroluminescent strip must be provided with its own source of power as shown in FIG. 3. The panel again comprises a conductive transparent layer 11, onto which are printed strips 21, 22 of electroluminescent material. Onto each electroluminescent strip 21, 22 is printed a corresponding dielectric strip 23, 24. A conductive strip 25, 26 is then printed onto each dielectric strip. In order to activate one of the two arrays of electroluminescent strips 21 to emit light 27, an alternating voltage is provided between every other conductive strip 25 and the conductive transparent layer 11. The other array of strips 22 can be activated by providing an alternating voltage between their corresponding conductive strips 26 and the conductive transparent layer 11.

The panel shown in FIG. 3 is expensive and difficult to manufacture. As mentioned above, the provision of the conductive transparent layer is expensive. In addition, the dielectric strips 23, 24 must be laid down accurately on top of the corresponding electroluminescent strips 21, 22, and the conductive strips 25, 26 must similarly be laid down accurately on top of the dielectric strips 23, 24. If there is any contact between a dielectric strip 23, 24 or a conductive strip 25, 26 and the conductive transparent layer 11, the corresponding electroluminescent strip 21, 22 will not operate.

In accordance with a first aspect of the present invention there is provided a light-emitting panel, comprising: a transparent substrate; a plurality of electroluminescent elements on the surface of the transparent substrate; and electrical supply means arranged between the electroluminescent elements, arranged so that an alternating voltage can be applied across each of the electroluminescent elements in a direction substantially parallel to the surface of the transparent substrate.

The electrical supply means preferably comprises a plurality of dielectric elements located between the electroluminescent elements, and a plurality of conductive elements in contact with the dielectric elements, although it is possible to activate the electroluminescent elements using a dielectric element in every other gap, with the other gaps containing only conductive elements. The electroluminescent elements (and dielectric and conductive elements) may be in the form of elongate strips.

Such a panel has the advantage that it is cheap and simple to manufacture. No conductive transparent layer is required, removing the need for difficult deposition under vacuum. Furthermore, the accuracy required for the deposition of individual strips is greatly reduced, allowing the panel to be manufactured using standard screen printing.

An alternating voltage source is preferably connected to the conductive elements. This may be done in such a way that the charge on adjacent dielectric elements oscillates so as to activate all of the electroluminescent elements simultaneously. Alternatively, the conductive elements may be connected in pairs so that alternate electroluminescent elements are activated. As a further alternative, the conductive elements may be connected in groups of three or more, so that every third or fourth electroluminescent element is activated.

These arrangements allow arrays of elements to be preferentially activated. If alternate elements are activated one night, the other elements may be activated the following night. If the panel is used in a sign, this greatly increases the life of the sign.

A further alternative allows for the sequential operation of the electroluminescent elements so as to give the impression that a light source moves along the panel.

Each dielectric element may extend at a proximal side to the surface of the transparent substrate at a gap between adjacent electroluminescent elements, and protrude at a distal side further away from the substrate than the electroluminescent elements. The conductive elements may then be located on the distal side of the dielectric elements.

As an alternative, each conductive element may be located at the surface of the transparent substrate in a gap between adjacent electroluminescent elements, completely enclosed by a dielectric element so that it does not contact an electroluminescent element.

The electroluminescent elements may emit light of different colours, and may be arranged into first and second arrays of electroluminescent elements, each array emitting light of a different colour. Furthermore, in accordance with one aspect of the invention there is provided a light-emitting panel comprising a first array of electroluminescent elements arranged to emit light of a first colour, and a second array of electroluminescent elements arranged to emit light of a second colour.

The panel may comprise further arrays of electroluminescent elements emitting light of yet further different colours. The electroluminescent elements in different arrays may activable simultaneously so that the panel appears to emit light of a colour made up of a combination of the colours emitted by the different arrays. The intensity of light emitted by different arrays may be variable so that the apparent shade of light emitted by the panel is variable in response to a change in the intensity of light emitted by one or more the arrays relative to the light emitted by the other array(s).

A transparent layer may be arranged on the opposite side of the panel to the transparent substrate. This allows light to be emitted from both sides of the panel. The whole panel may be hermetically sealed so that it is maintenance-free for its whole life.

The panel may comprise a plurality of selectively actuatable arrays of electroluminescent elements, so that different shapes can be illuminated by activating different arrays. The arrays may be at least partially superimposed over each other.

The transparent substrate may be a curved surface. This allows electroluminescent panels to be formed for example as cylinders.

In accordance with a preferred embodiment of the invention there is provided a sign panel comprising a light-emitting panel as described above having a transparent retroreflective layer arranged on the transparent substrate. A photoresistor may be provided on the surface of the transparent substrate for detecting the level of ambient light falling on the panel.

In accordance with a second aspect of the present invention there is provided a method of manufacturing a light-emitting panel, comprising: depositing a plurality of electroluminescent elements on a transparent substrate; depositing a plurality of dielectric elements on the substrate in the gaps between the electroluminescent elements so that the dielectric elements extend further away from the substrate than the electroluminescent elements; and depositing a conductive element on the top of each dielectric element.

Some preferred embodiments of the invention will now be described by way of example only and with reference to the accompanying drawings, in which:

FIG. 1 shows an electroluminescent panel comprising two arrays of alternating electroluminescent strips;

FIG. 2 is a cross section through a typical unsegmented electroluminescent panel;

FIG. 3 is a cross section through a known segmented electroluminescent panel;

FIG. 4 is a cross section through a road sign illuminated using an electroluminescent panel;

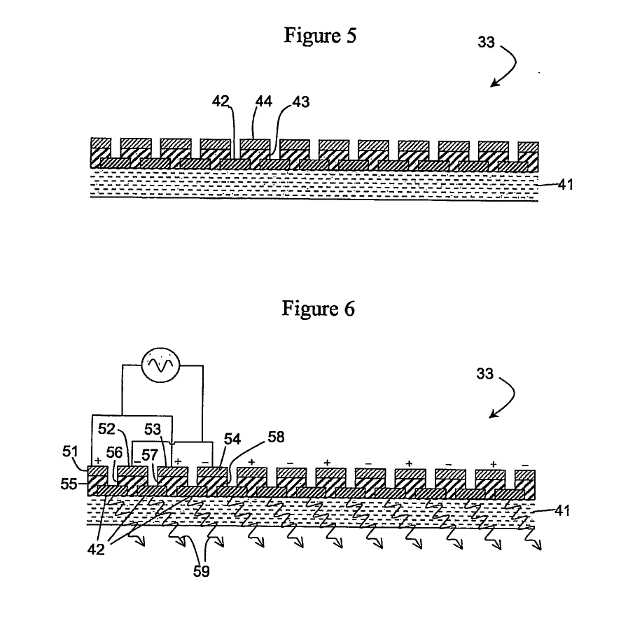

FIG. 5 is a cross section through a segmented electroluminescent panel suitable for use in the sign of FIG. 4;

FIG. 6 shows the electroluminescent panel of FIG. 5 with an alternating voltage supplied to activate all electroluminescent strips in the panel;

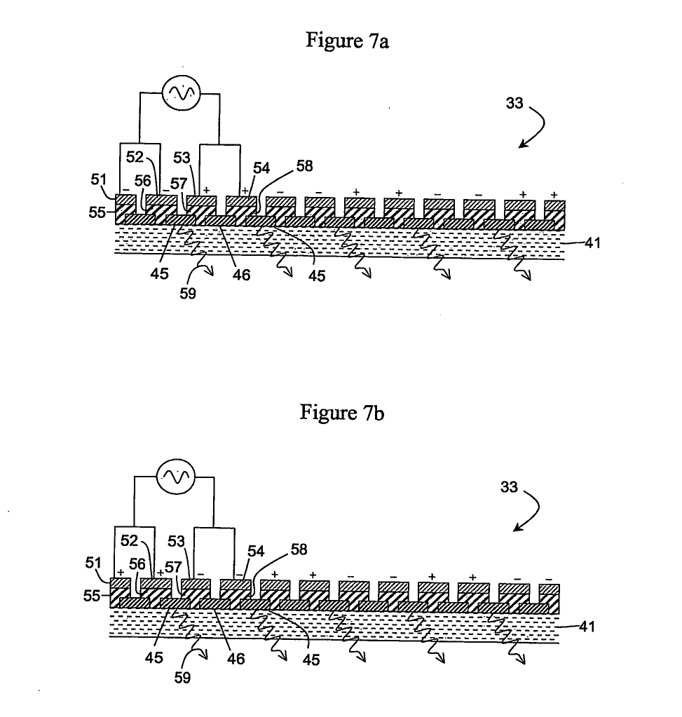

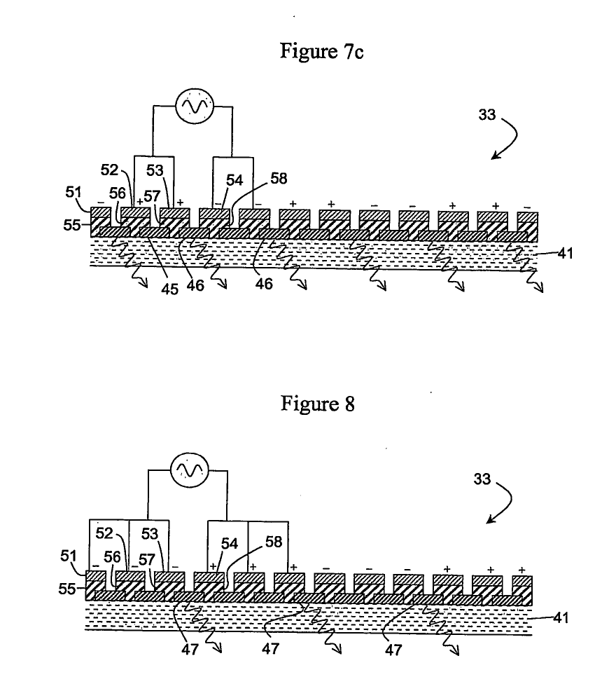

FIG. 7a shows the electroluminescent panel of FIG. 5 with an alternating voltage supplied to conductive strips in pairs so as to activate alternate electroluminescent strips;

FIG. 7b shows the electroluminescent panel of FIG. 7a at the opposite end of the alternating voltage cycle, when all of the dielectric strips have reversed their polarity;

FIG. 7c shows the electroluminescent panel of FIG. 7a with the alternating voltage applied to different pairs of conductive strips;

FIG. 8 shows the electroluminescent panel of FIG. 5 with an alternating voltage applied to the conductive strips in sets of three so as to activate every third electroluminescent strip;

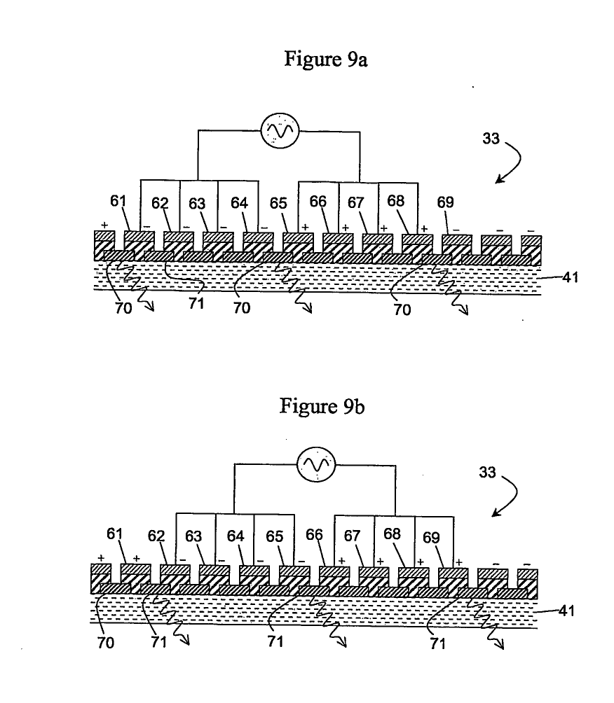

FIG. 9a shows the first stage in a simulated movement across the surface of the panel;

FIG. 9b shows the second stage of the simulated movement across the surface of the panel;

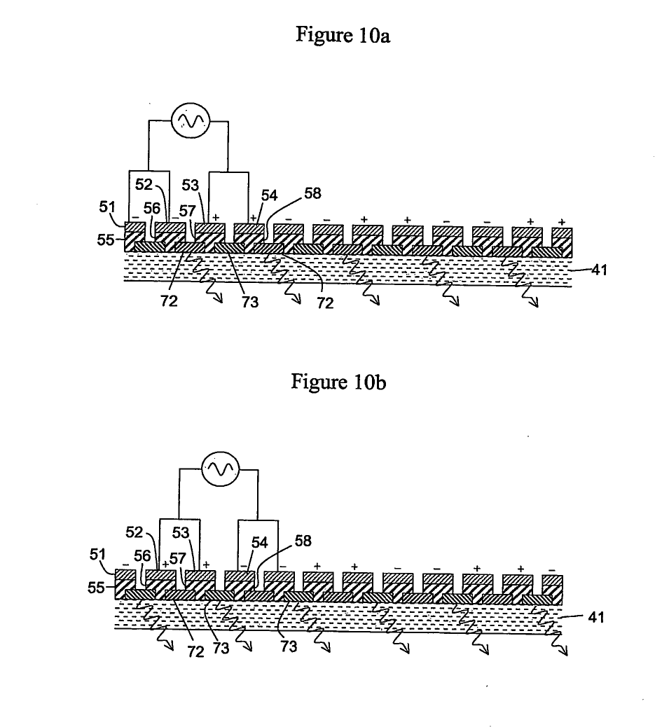

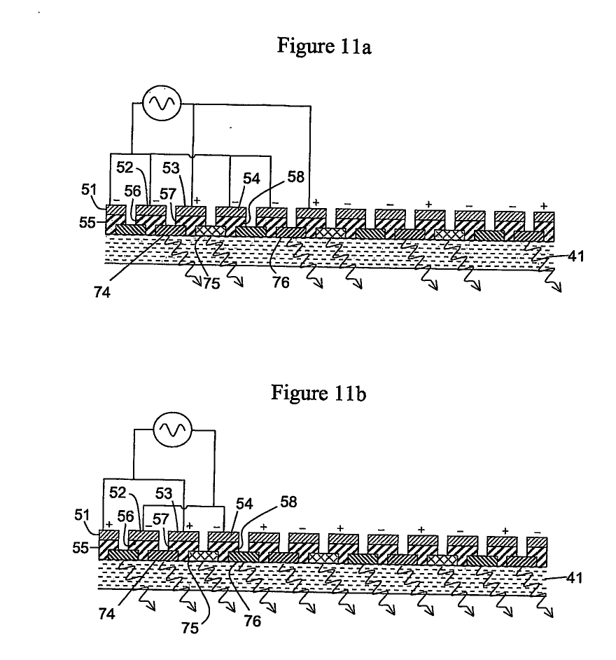

FIGS. 10a and 10b show an electroluminescent panel having two arrays of differently coloured strips;

FIG. 11a shows an electroluminescent panel emitting yellow light by combining light from green and red electroluminescent strips;

FIG. 11b shows an electroluminescent panel emitting white light by combining light from red, green and blue electroluminescent strips;

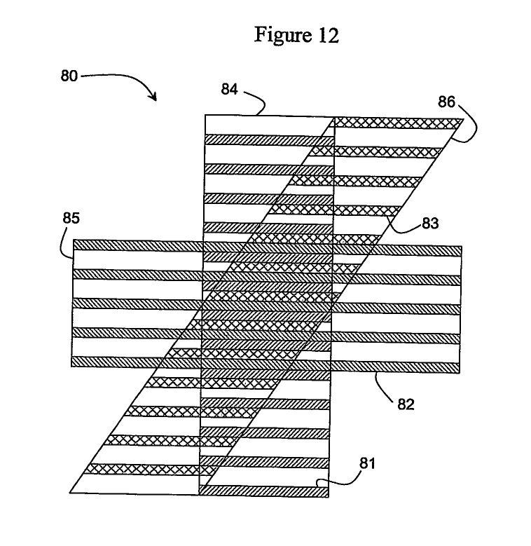

FIG. 12 is a plan view of three superposed arrays of electroluminescent strips forming different shapes;

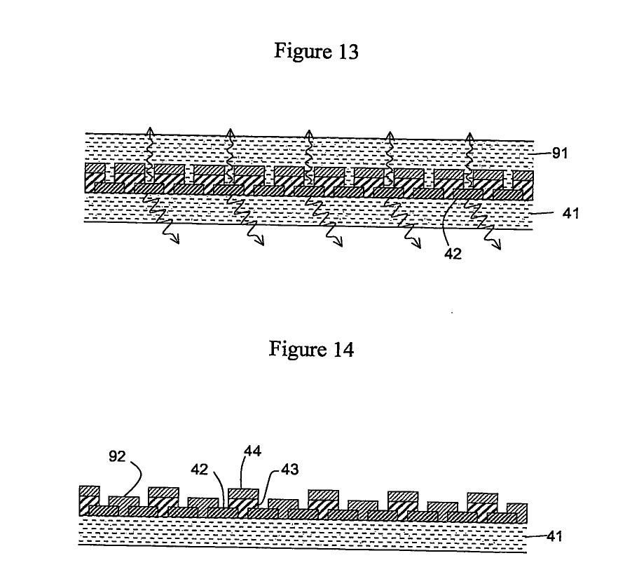

FIG. 13 shows an electroluminescent panel emitting light from both sides;

FIG. 14 is a cross section through an alternative embodiment of an electroluminescent panel having fewer dielectric strips; and

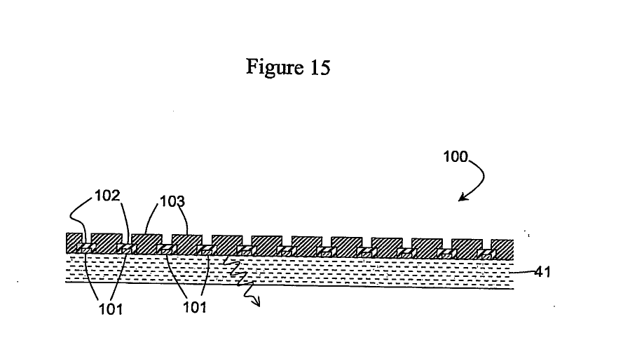

FIG. 15 is a cross section through a further alternative embodiment of an electroluminescent panel.

FIG. 4 is a cross section through a road sign 30. The sign 30 consists of an aluminium or plastic back plate 31, onto which is laminated a white layer 32, an electroluminescent panel 33, and a retro-reflective layer 34 consisting of a transparent or translucent retro-reflective material. A sign panel 35 is arranged as a transparent, partially coloured, overlay on the retro-reflective layer 34. Additional information can be provided by the provision of more overlays or more retro-reflective elements (not shown) attached to the front of the sign 30. Light 36 emitted from the electroluminescent panel 33 passes through the retro-reflective layer 34 and transparent overlay 35.

FIG. 5 is a cross-section through a segmented electroluminescent panel 33 suitable for use in the sign 30 of FIG. 4. The panel comprises a transparent outer window 41, onto which is deposited an array of strips 42 of electroluminescent material. In the gaps between the electroluminescent strips 42 are strips 43 of dielectric material. These dielectric strips 43 extend to the surface of the transparent window 41, and protrude at the other edge above the tops of the electroluminescent strips 42. Each dielectric strip is capped with a strip 44 of conductive material.

As shown in FIG. 6, an alternating voltage can be applied across each electroluminescent strip 42 via adjacent conductive strips 51, 52 and their associated dielectric strips 53, 54, which fill the gaps either side of the electroluminescent strip 42.

When a voltage is applied to adjacent conductive strips 51, 52 the charge is held momentarily by the corresponding dielectric strips 55, 56. This causes the electroluminescent strip 42 between to become polarised, causing the emission of holes and electrons at opposite ends of doped material within the electroluminescent material. As the voltage alternates (typically at 100-400 V and 200-1000 Hz) the polarity is reversed, causing the electroluminescent strip 42 to emit light 59 through the transparent window 41. In the arrangement shown in FIG. 6, the alternating voltage is applied to alternate conductive strips 51, 52, 53, 54 causing all of the electroluminescent strips 42 in the panel to emit light 59. It will be appreciated that the alternating voltage, shown applied to four conducting strips 51, 52, 53, 54 in FIG. 6, will be applied across the whole panel.

FIG. 7 shows a similar electroluminescent panel 33, with the conductive strips 51, 52, 53, 54 connected in pairs. FIG. 7a shows the charges associated with the conductive strips 51, 52, 53, 54 and their associated dielectric strips 55, 56, 57, 58 at one peak in the voltage cycle, and FIG. 7b shows the charges at the opposite peak, when polarity has been reversed. The polarity of the dielectric strips 55, 56 within a pair does not change relative to one another, so the electroluminescent strip 46 located between two such dielectric strips 55, 56 does not emit light. The polarity changes only across every other electroluminescent strip 45 to cause it to emit light 59.

The following day the driving circuit is switched as shown in FIG. 7c so that the conducting 52, 53 and dielectric 56, 57 strips which originally changed polarity relative to each other now form pairs. This means that the original set of alternate electroluminescent strips 45 no longer emit light, but the other set of alternate electroluminescent strips 46 now emit light 59 in their place.

On a traditional electroluminescent panel, the maximum efficiency is typically achieved when powered at 400 Hz and 160 V, producing a light emission of 40 cd m⁻². This light level could be reduced by reducing the voltage, frequency or both. This would extend the life of the panel, but not by as much as may be predicted by theory because the panel is not being driven at its most efficient point. By lighting alternative strips, for example on a daily basis, the light output can be reduced to 15 cd m⁻², and the electroluminescent material still run at its most efficient point. In effect, two panels are thus provided together, and the overall life of the panel is maximised.

It will be appreciated that the switching circuit can easily be modified so that only one strip in three, or one in four or more, emits light at any one time. FIG. 8 is an example of a panel 33 switched so that the conducting strips 51, 52, 53 are connected in sets of three. Now only every third electroluminescent strip 47 emits light 59. This allows the life of the sign to be prolonged still further by activating three different arrays on three different days.

Furthermore, using a suitable electronic control mechanism it is possible to induce a degree of simulated movement in the panel by lighting one of a series of strips alternately, as shown in FIG. 9. FIG. 9a shows an arrangement where in which the conductive strips 61-64, 65-68 are connected together in sets of four, so that every fourth electroluminescent strip 70 emits light 59. A short time later, the driving circuit is switched so that the sets of four conductive strips 62-65, 66-69 connected together move one strip to the right. This means that the next electroluminescent strips along 71 now emit light. This sequence can be repeated to give the appearance of light emitters moving across the sign. This could be used, for example, to highlight the direction indicated by an arrow on the sign.

The electroluminescent panels described above are simple to manufacture. Because the electroluminescent strips are powered from the sides, rather than in front and behind, the need for an expensive transparent conductive layer is removed, and the electroluminescent strips can be laid down directly on an ordinary transparent layer. Furthermore, the precision required to deposit the subsequent dielectric and conductive layers is reduced This greatly simplifies the technology needed to produce the electroluminescent panel, and enables it to be produced by standard screen printing or other low-cost techniques.

In addition, since the production of the panel is possible using simple printing techniques, there is no requirement that the panel must be in the form of a flat sheet. The panel could, for example, be printed directly onto a cylindrical surface using rotary printing techniques. This would allow the panel to be used, for example, in a road sign providing information in all directions, but it will be appreciated that other uses would be possible. For example, the panel could be used to manufacture a domestic light fitting in the form of a cylinder emitting light from the surface thereof. Alternatively, the panel could be printed onto, for example, part of the body of a vehicle or bicycle to provide additional illumination.

In addition, it is possible to get the electroluminescent strips closer together than in known panels, due to the fact that the dielectric strips are placed in the gaps between the electroluminescent strips. It is possible to get the gap as small as 0.2 mm, and in fact it is only limited by the constraints of screen printing.

Furthermore, it is straightforward to laminate the whole assembly between plastic sheets, one of which is clear so as to act as a window. With suitable sealed exits for electrical supply wires the structure will be maintenance free for its whole life.

Although the segmented electroluminescent panel has been described for use with an illuminated road sign, it will be appreciated that it is not limited to such use. The segmented panel is particularly useful for any application where an extension to the life of a panel is desired, because arrays of electroluminescent strips can be activated alternately. However, if all of the strips are activated simultaneously (as shown in FIG. 6) then the whole panel can be illuminated at maximum brightness. A segmented electroluminescent panel as described above thus provides an inexpensive alternative to known electroluminescent panels without the need for prolonging the life of such panels.

The electroluminescent strips need not all emit light of the same wavelength. FIG. 10 shows a panel like the panel shown in FIG. 7, in which the electroluminescent strips are arranged in two alternating arrays emitting light of different colours. The electroluminescent strips 72 in a first array emit blue light, and the strips 73 in a second array emit green light. Thus when the conductive strips 51-54 are connected as shown in FIG. 10a, the electroluminescent strips 72 of the first array emit blue light, the strips 73 of the second array are not activated, and the panel appears to emit blue light. If the conductive strips 51-54 are connected as shown in FIG. 10b, then the electroluminescent strips 72 of the first array are not activated, the strips 73 of the second array emit green light, and the panel appears to emit green light This arrangement allows a single electroluminescent panel to be used to emit light of different colours.

It will be appreciated that there is no restriction to the use of only two colours. There could be arrays of strips of three, four, or even more different colours so that the panel could be lit up in a number of different colours. Clearly, the more different arrays there are (and thus the more spaced apart the illuminated strips) the more likely it is that a viewer would be able to perceive the segmentation of the panel. This could be overcome by incorporating a diffuser layer (not shown) beyond the transparent substrate.

Different colours are also obtainable by combining the output from strips. FIG. 11 shows a panel, like the panel of FIG. 10, having arrays of red 74, green 75 and blue 76 electroluminescent strips. In FIG. 11a the conductive strips 51-54 are connected so that the red 74 and green 75 electroluminescent strips emit light and the blue 76 strips are not activated. To the viewer, the light emitted by the panel appears to be yellow (red and green combined). In FIG. 11b the conductive strips 51-54 are connected so that all of the strips 74, 75, 76 are illuminated and the panel appears to emit white light

Thus with three arrays of electroluminescent strips, each emitting a primary colour, it is possible to combine the light emitted by the strips to produce six separate colours or white. It is possible to gain even more control over the colour emitted if the power supplied to the strips is varied. For example, the panel may be operated so that red electroluminescent strips emit light at maximum intensity, and green electroluminescent strips emit light at a lower intensity. The colour perceived by the viewer would be orange. Thus the panel can be used to obtain light of almost any shade required.

This availability of any colour, including white, means that electroluminescent panels may be used for a large variety of different purposes. A few examples include mood lighting, office or domestic lighting, railway station signs, advertising signs, and safety signs.

It will also be appreciated that the provision and selective actuation of arrays of differently coloured electroluminescent strips may also apply to segmented electroluminescent panels not having electroluminescent strips powered from the sides. For example, the segmented panel of FIG. 3 could be provided with arrays of differently coloured electroluminescent strips.

A segmented electroluminescent panel also allows the possibility of superimposing arrays of different shapes to allow shapes to be individually illuminated. FIG. 12 shows a plan view of a panel 80 having an array of blue electroluminescent strips 81 arranged to form a vertical stripe 84, an array of green electroluminescent strips 82 in the form of a horizontal stripe 85, and an array of red electroluminescent strips 83 in the form of a diagonal stripe 86. Thus the panel 80 can be actuated to display a blue vertical stripe, green horizontal stripe or red diagonal stripe. Of course, there is no requirement that the strips are different colours: the panel could simply be actuated to display different shapes.

This allows information to be selectively displayed by the panel. For example, the panel could be used in a road sign displaying a speed limit, and the arrays could be shaped to show different numbers so that any required speed limit could be illuminated by the sign.

It is also possible to illuminate both sides of the panel simultaneously. A suitable arrangement is shown in FIG. 13, which is provided with transparent backing 91 in addition to the transparent window 41.

When the electroluminescent panel is used to illuminate a sign, it is often desirable that the sign should only be illuminated at night Some means of detecting the external light falling on the sign is therefore required. If the panel is manufactured by screen printing, a screen printed photoresistor can be added to the panel for use as a light sensor. This can, for example, be located around the edge of the panel, enabling it to be outside the area covered by the retroreflective coating.

In addition, when the panel is used to illuminate a sign, it can be powered by mains electricity, although it is preferred to include a power supply buried in the ground. This may include a rechargeable battery and an electronic control system for controlling which electroluminescent strips are actuated at any one time. When power is supplied by a rechargeable battery it will be necessary to provide a dc/ac converter, since the electroluminescent strips are driven by an alternating voltage. The power supply will preferably be connected to the panel via leads running through the middle of a post supporting the sign. A sign of 270 mm diameter requires power at about 100 V (ac) at about 400 to about 700 Hz to provide 65 cd, the minimum requirement.

Photovoltaic cells may be mounted on the sign to supply power during the day to the rechargeable battery, enabling the battery to be recharged during the day so as to supply power to the panel during the night.

It will be appreciated that alternatives to the above described embodiments may still fall within the scope of the invention. For example, FIG. 14 shows an arrangement in which alternate gaps 92 between adjacent electroluminescent strips contain a dielectric strip 43 topped by a conductive strip 44, in a similar manner to the panel shown in FIG. 5. In the other gaps 93 there is no dielectric element, but a conductive strip 94 is laid down directly onto the substrate in contact with the electroluminescent strips 42. In theory, there is no need for any dielectric elements at all but in practice electroluminescent strips burn out very quickly if powered directly via a conductive strip on both sides.

FIG. 15 shows a cross-section through a further alternative embodiment of an electroluminescent panel. The panel 100 has been produced in reverse. Conductive strips 101 are laid down on the transparent window 41. These conductive strips 101 are then overlaid with dielectric strips 102 so that they are completely covered. Electroluminescent strips 103 are then laid down into the gaps between the dielectric strips 102. The operation of the panel is the same as for the panels previously described, with alternating voltages applied across the electroluminescent strips 103 via the conductive strips 101 and dielectric strips 102.

In addition, there is no need for arrays of strips to be used alternately to prolong the lifetime of a road sign. One set of strips could be activated continuously until the light emitted by such strips has fallen below an acceptable level, and then an alternative set of strips could be activated.

Furthermore, although the embodiment described utilises electroluminescent strips, it will be appreciated that the panel could comprise electroluminescent elements arranged as “spots” in a 2 dimensional array. Dielectric elements would be located between the electroluminescent elements in the same way as if they were strips.

1. A light-emitting panel, comprising:
a transparent substrate;
a plurality of electroluminescent elements on the surface of the transparent substrate; and
electrical supply means arranged between the electroluminescent elements, arranged so that an alternating voltage can be applied across each of the electroluminescent elements in a direction substantially parallel to the surface of the transparent substrate.

2. A light-emitting panel as claimed in claim 1, wherein the electroluminescent elements are in the form of elongate strips of electroluminescent material.

3. A light-emitting panel as claimed in claim 1, wherein the electrical supply means comprises a plurality of dielectric elements located between the electroluminescent elements, and a plurality of conductive elements in contact with the dielectric elements.

4. A light-emitting panel as claimed in claim 3, further comprising an alternating voltage source connected to the conductive elements in such a way that the charge on adjacent dielectric elements oscillates and all of the electroluminescent elements are activated simultaneously.

5. A light-emitting panel as claimed in claim 3, further comprising an alternating voltage source connected to the conductive elements in pairs so that alternate electroluminescent elements are activated.

6. A light-emitting panel as claimed in claim 3, further comprising an alternating voltage source connected to the conductive elements in such a way that three or more adjacent dielectric elements are raised to the same voltage, so that the spacing between activated electroluminescent elements is at least two.

7. A light-emitting panel as claimed in claim 3, further comprising an alternating voltage source connected to the conductive elements in such a way that adjacent electroluminescent elements are sequentially activated so as to give the impression that a light source moves along the panel.

8. A light-emitting panel as claimed in claim 3, wherein each dielectric element extends at a proximal side to the surface of the transparent substrate at a gap between adjacent electroluminescent elements, and protrudes at a distal side further away from the substrate than the electroluminescent elements.

9. A light-emitting panel as claimed in claim 8, wherein the conductive elements are located on the distal side of the dielectric elements.

10. A light-emitting panel as claimed in claims 3, wherein each conductive element is located at the surface of the transparent substrate in a gap between adjacent electroluminescent elements, and is completely enclosed by a dielectric element so that it does not contact an electroluminescent element.

11. A light-emitting panel as claimed in claim 1, wherein the electroluminescent elements emit light of different colours.

12. A light-emitting panel, comprising a transparent substrate, a first array of electroluminescent elements arranged to emit light of a first colour, and a second array of electroluminescent elements arranged to emit light of a second colour.

13. A light-emitting panel comprising a first array of electroluminescent elements arranged to emit light of a first colour, and a second array of electroluminescent elements arranged to emit light of a second colour.

14. A light-emitting panel as claimed in claim 13, further comprising a third array of electroluminescent elements arranged to emit light of a third colour.

15. A light-emitting panel as claimed in claim 13, arranged so that the electroluminescent elements in different arrays are activatable simultaneously so that the panel appears to emit light of a colour made up of a combination of the colours emitted by the different arrays.

16. A light-emitting panel as claimed in claim 15, wherein the intensity of light emitted by different arrays is variable so that the apparent shade of light emitted by the panel is variable in response to a change in the intensity of light emitted by one or more the arrays relative to the light emitted by the other array(s).

17. A light-emitting panel as claimed in claim 1, further comprising a diffuser layer.

18. A light-emitting panel as claimed in claim 1, further comprising a transparent layer arranged on the opposite side of the panel to the transparent substrate.

19. A light-emitting panel as claimed in claim 18, arranged to emit light through the transparent layer and the transparent substrate.

20. A light-emitting panel, comprising a plurality of selectively actuatable arrays of electroluminescent elements, so that different shapes can be illuminated by activating different arrays.

21. A light-emitting panel as claimed in claim 20, wherein the arrays are at least partially superimposed on one another.

22. A light-emitting panel as claimed in claim 1, wherein the electrical supply means comprises a plurality of dielectric elements located between every other pair of electroluminescent elements, each dielectric element in contact with a conductive element, and a conductive element located in each gap between adjacent electroluminescent elements not occupied by a dielectric element.

23. A light-emitting panel, comprising:
a transparent substrate;
a plurality of electroluminescent elements on the surface of the transparent substrate;
a plurality of dielectric elements located between the electroluminescent elements; and
a plurality of conductive elements in contact with the dielectric elements, arranged so that a voltage can be applied across each of the plurality of electroluminescent elements.

24. A light-emitting panel as claimed in claim 23, wherein the transparent substrate is a curved surface.

25. A light-emitting panel as claimed in claim 22, wherein the curved surface is a cylindrical surface.

26. A sign panel, comprising:
a light-emitting panel as claimed in any preceding claim; and
a transparent, retroreflective layer arranged on the opposite side of the transparent substrate to the electroluminescent elements.

27. A sign panel as claimed in claim 26, further comprising a photoresistor on the surface of the transparent substrate for detecting the level of ambient light falling on the panel.

28. A method of manufacturing a light-emitting panel, comprising:
depositing a plurality of electroluminescent elements on a transparent substrate;
depositing a plurality of dielectric elements on the substrate in the gaps between the electroluminescent elements so that the dielectric elements extend further away from the substrate than the electroluminescent elements; and
depositing a conductive element on the top of each dielectric element.

29. A method of emitting light from a light-emitting panel, comprising:
supplying an alternating voltage to alternate conductive elements so that each electroluminescent element is provided with an alternating voltage across it and emits light.

30. A method of emitting light from a light-emitting panel, comprising:
supplying an alternating voltage to adjacent pairs of conductive elements so as to activate a first set of alternate electroluminescent elements to emit light.

31. A method as claimed in claim 30, further comprising altering the adjacent pairs of conductive elements to which the alternating voltage is supplied so as to activate a second set of alternate electroluminescent elements to emit light.
